(19) United States
(12) Patent Application Publication
(10) Pub. No.: US 2023/0112914 A1
(43) Pub. Date: Apr. 13, 2023

(54) LOW-LOSS QUASI-CIRCULATOR

(71) Applicant: Korea Electronics Technology Institute, Seongnam-si (KR)

(72) Inventors: Ki Jin KIM, Yongin-si (KR); Kwang Ho AHN, Yongin-si (KR); Soo Chang CHAE, Changwon-si (KR)

(73) Assignee: Korea Electronics Technology Institute, Seongnam-si (KR)

(21) Appl. No.: 17/563,257

(22) Filed: Dec. 28, 2021

(30) Foreign Application Priority Data
Oct. 12, 2021 (KR) 10-2021-0134586

(51) Int. Cl. H01P 1/38; H04B 1/40; H03F 3/19

(52) U.S. Cl. CPC H01P 1/38; H04B 1/40; H03F 3/19; H03F 2200/451

(57) ABSTRACT

There is provided a quasi-circulator. The quasi-circulator includes: a first coupler having an input end connected to a transmission end; a first amplifier having an input end connected to an output end of the first coupler; a second amplifier having an input end connected to the output end of the first coupler; a second coupler having one end connected to an output end of the first amplifier and an output end of the second amplifier, and the other end connected to an antenna; and a third coupler having one end connected to the output end of the first amplifier and the output end of the second amplifier, and the other end connected to a reception end. Accordingly, a loss occurring at the quasi-circulator is minimized, and eventually, efficiency of an RF FEM employed in an ultrahigh frequency radar system is enhanced.

### PRIORITY

This application is based on and claims priority under 35 U.S.C. § 119 to Korean Patent Application No. 10-2021-0134586, filed on Oct. 12, 2021, in the Korean Intellectual Property Office, the disclosure of which is herein incorporated by reference in its entirety.

### BACKGROUND

### Field

The present disclosure relates generally to communication component-related technology, and more particularly, to a circulator which is needed for a transmission end and a reception end to share and to use an antenna.

### Description of Related Art

FIG. 1 shows a radio frequency front end module (RF FEM) of a normal communication system which uses time division duplexing (TDD). Tx and Rx use the same communication frequency, but transmit and receive signals at different times. Accordingly, in this structure, an antenna connection is short-circuited to Tx and Rx through a switch only for a defined time according to each mode. By doing this, a signal of Tx is restricted from being connected to a path of Rx.

If Tx is a radar system that transmits signals in the air through a power amplifier (PA) and receives radio frequency (RF) energy reflected from an object at a specific distance therefrom, there is no defined time shown in FIG. 1, and it may be difficult to use a switch in an FEM structure. Accordingly, many systems use a structure in which respective antennas are connected to a transmitter and a receiver as shown in FIG. 2, and restricts a signal of Tx from being coupled with Rx. However, this structure has a problem that two times more physical antennas than in FIG. 1 should be arranged and thus a size of a module increases.

FIG. 3 illustrates a structure of an RF system in which Tx and Rx are separated by using a circulator. The circulator is a block that has directionality of a signal as shown in FIG. 3. The circulator is often used if TDD is not used in a radar system. However, the circulator has a problem that its insertion loss is great and its price is high. In addition, it may be more difficult to apply the structure of FIG. 3, considering the trend of a recent radar operating frequency increasing up to 80 GHz. This is because the existing circulator is used only in the products operating at an operating frequency of 10 GHz or less. Therefore, in many cases, circulator structures are directly designed in various methods.

FIG. 4 illustrates a structure of a circulator using a coupler. If port 1 is a transmission port and port 2 is an antenna port, the structure ideally shows a loss of 6 dB through two couplers. Although an amplifier (AMP) between the two ports compensates for an amplitude, the amplifier is included in a Tx path that requires high output, and thus, there may be a problem that a better amplifier than an amplifier used in an original Tx circuit is required.

In addition, if a path from port 2 to port 3 is an Rx path, a loss of 3 dB occurs at port 2 through the coupler, first, resulting in an increase of a noise index of a receiver by 3 dB. Therefore, this structure has no choice but to have a high noise index even if there is a low noise amplifier (LNA) at a rear end. When the structure is implemented in a compound semiconductor process MMIC circuit, an amplitude (an amplitude error of 0.3 dB) shows a bandwidth of 15% and a size is designed by 6 mm×6 mm (with reference to 4.5 GHz). However, recent mobile communication systems require a bandwidth of 20% or higher, and a bandwidth of a 5G hybrid coupler is not sufficient, and simultaneously, a chip consumption area that is occupied by a hybrid coupler is large and the efficiency of the hybrid coupler is degraded.

FIG. 5 illustrates a structure of a quasi-circulator. In a circulator, a signal is transmitted from port 3 to port 1, but the quasi-circulator does not have a path from port 3 to port 1 and is more advantageous to an RF FEM. The quasi-circulator adopts a structure for increasing isolation of port 1 and port 3 while adjusting internal impedances Z1 to Z4 of a coupler in comparison with a normal coupler. However, this structure also has a problem that a coupler loss of 3 dB+ occurs both at Tx and Rx.

### SUMMARY

To address the above-discussed deficiencies of the prior art, it is a primary object of the present disclosure to provide a quasi-circulator of a structure which is capable of minimizing a loss, as a solution to increase efficiency of an RF FEM of an ultrahigh frequency radar system.

According to an embodiment of the present disclosure to achieve the above-described object, a quasi-circulator includes: a first coupler having an input end connected to a transmission end; a first amplifier having an input end connected to an output end of the first coupler; a second amplifier having an input end connected to the output end of the first coupler; a second coupler having one end connected to an output end of the first amplifier and an output end of the second amplifier, and the other end connected to an antenna; and a third coupler having one end connected to the output end of the first amplifier and the output end of the second amplifier, and the other end connected to a reception end.

The first coupler may distribute a transmission signal inputted through the input end into two signals having a phase difference of 90 degrees, and may output the signals, the first amplifier may amplify one of the signals outputted from the output end of the first coupler, the second amplifier may amplify the other one of the signals outputted from the output end of the first coupler, and the second coupler may convert the phase difference between the output signal of the first amplifier and the output signal of the second amplifier into 0 degree, and may transmit the signals to the antenna.

The signals outputted from the first amplifier and the second amplifier may have power equally distributed and transmitted to the second coupler and the third coupler.

An impedance when the second coupler and the third coupler are seen from the output end of the first amplifier may be a sum of an impedance of the second coupler and an impedance of the third coupler, an impedance when the second coupler and the third coupler are seen from the output end of the second amplifier may be the sum of the impedance of the second coupler and the impedance of the third coupler, and the impedance of the second coupler may be equal to the impedance of the third coupler.

The third coupler may offset the phase difference between the output signal of the first amplifier and the output signal of the second amplifier by converting the phase difference into 180 degrees.

The second coupler may distribute a reception signal inputted through the antenna into two signals having a phase difference of 90 degrees, and may output the signals, and the third coupler may convert the phase difference between output signals of the second coupler into 0 degree, and may transmit the signals to the reception end.

The first amplifier and the second amplifier may block the output signals of the second coupler.

According to another embodiment of the present disclosure, a communication method includes the steps of: distributing, by a first coupler, a transmission signal inputted from a transmission end into two signals, and output the signals; amplifying, by a first amplifier, one of the distributed transmission signals; amplifying, by a second amplifier, the other one of the distributed transmission signals; transmitting, by a second coupler, the amplified transmission signals to an antenna; and offsetting, by a third coupler, the amplified transmission signals at a reception end.

According to embodiments of the present disclosure as described above, a loss occurring at the quasi-circulator is minimized, and eventually, efficiency of an RF FEM employed in an ultrahigh frequency radar system is enhanced.

Other aspects, advantages, and salient features of the invention will become apparent to those skilled in the art from the following detailed description, which, taken in conjunction with the annexed drawings, discloses exemplary embodiments of the invention.

Before undertaking the DETAILED DESCRIPTION OF THE INVENTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is a view illustrating an RF FEM structure of a communication system;

FIG. 2 is an RF structure in which transmission and reception antennas are separated;

FIG. 3 is a view illustrating an RF FEM structure using a circulator;

FIG. 4 is a view illustrating a circulator design using a coupler;

FIG. 5 is a view illustrating a quasi-circulator structure; and

FIG. 6 is a view illustrating a structure of a low-loss quasi-circulator according to an embodiment of the present disclosure.

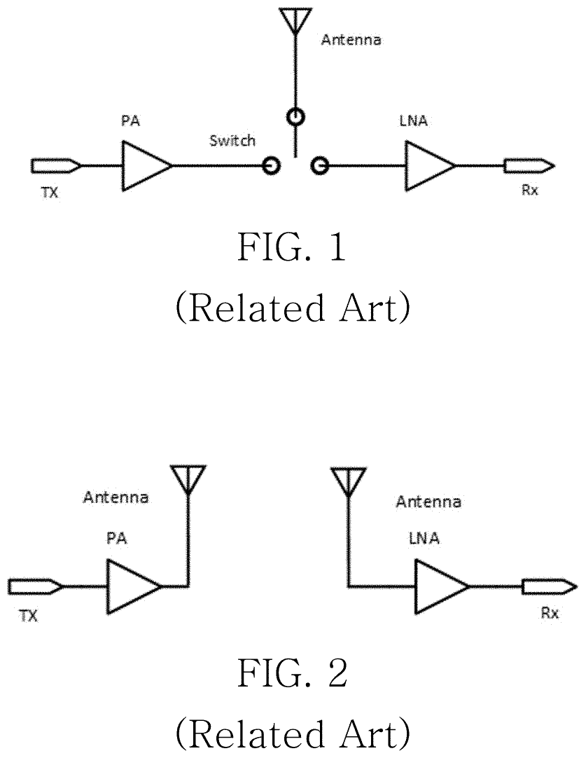

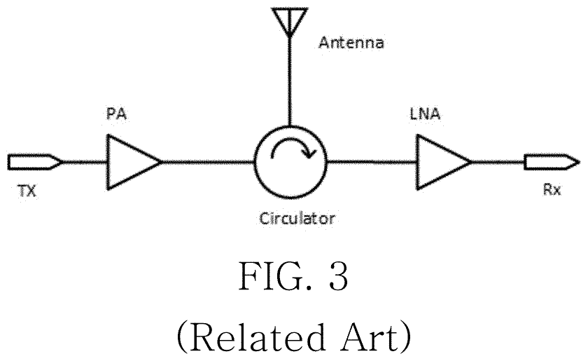

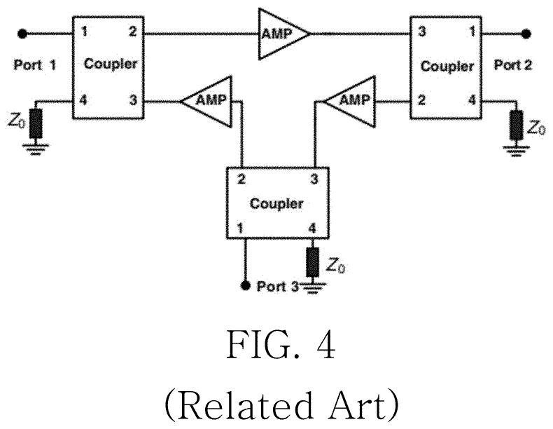

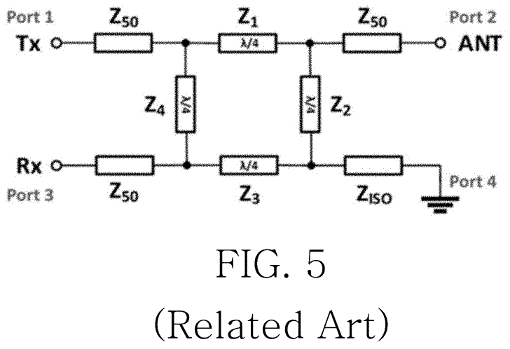

### DETAILED DESCRIPTION

Hereinafter, the present disclosure will be described in more detail with reference to the accompanying drawings.

Embodiments of the present disclosure suggest a low-loss quasi-circulator. In embodiments of the present disclosure, a quasi-circulator of a low loss is implemented by using two power amplifiers and three hybrid couplers, which is different from a related-art structure in which a loss is great at a transmission end a reception end.

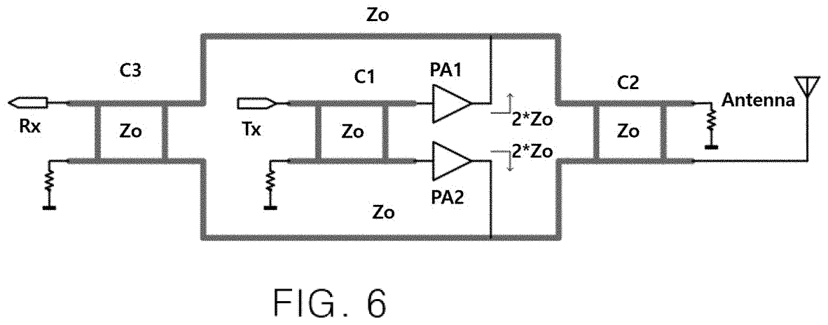

FIG. 6 is a view illustrating a structure of a low-loss quasi-circulator according to an embodiment of the present disclosure. As shown in the drawing, the quasi-circulator according to an embodiment may include a hybrid coupler-1 C1, a power amplifier-1 PA1, a power amplifier-2 PA2, a hybrid coupler-2 C2, and a hybrid coupler-3 C3.

The hybrid coupler-1 C1 has an input end connected to a transmission end Tx and an output end connected to the power amplifiers PA1, PA2. The hybrid coupler-1 C1 distributes a transmission signal inputted from the transmission end Tx to the power amplifiers PA1, PA2.

The power amplifiers PA1, PA2 have input ends connected to the output end of the hybrid coupler-1 C1, and have output ends connected to the hybrid coupler-2 C2 and the hybrid coupler-3 C3.

The hybrid coupler-2 C2 has one end connected to the output ends of the power amplifiers AP1, PA2, and the other end connected to an antenna. The hybrid coupler-2 C2 transmits the transmission signal outputted from the output ends of the power amplifiers PA1, PA2 to the antenna, and transmits a reception signal received at the antenna to the hybrid coupler-3 C3.

The hybrid coupler-3 C3 has one end connected to the output ends of the power amplifiers PA1, PA2, and the other end connected to a reception end Rx. The hybrid coupler-3 C3 transmits the reception signal of the antenna transmitted through the hybrid coupler-2 C2 to the reception end Rx.

On the other hand, an impedance 2*Zo when the hybrid coupler-2 C2 and the hybrid coupler-3 C3 are seen from the output end of the power amplifier-1 PA1 is a sum of an impedance Zo of the hybrid coupler-2 C2 and an impedance Zo of the hybrid coupler-3 C3.

Likewise, an impedance 2*Zo when the hybrid coupler-2 C2 and the hybrid coupler-3 C3 are seen from the output end of the power amplifier-2 PA2 is the sum of the impedance Zo of the hybrid coupler-2 C2 and the impedance Zo of the hybrid coupler-3 C3.

In addition, the hybrid coupler-1 C1, the hybrid coupler-2 C2, and the hybrid coupler-3 C3 are implemented equally, such that the impedance Zo is the same.

Power amplifiers do not have to be connected to the input end of the hybrid coupler-1 C1. This is because the power amplifiers PA1, PA2 at the output end perform the roles of power amplifiers at the input end. Accordingly, the power amplifiers PA1, PA2 are added to the output end of the hybrid coupler-1 C1, but the power amplifiers are omitted from the input end, and therefore, the whole area of the communication system is not regarded as increasing.

A transmission mode operation of the quasi-circulator according to an embodiment will be described in detail.

When a transmission signal is inputted from the transmission end Tx through the input end, the hybrid coupler-1 C1 distributes the inputted transmission signal into two signals having a phase difference of 90 degrees (a 0-degree signal having a phase of 0 degree and a 90-degree signal having a phase of 90 degrees), and outputs the signals.

Then, the power amplifier-1 PA1 amplifies and outputs the 0-degree signal, and the power amplifier-2 PA2 amplifies and outputs the 90-degree signal. The transmission signals outputted from the power amplifier-1 PA1 and the power amplifier-2 PA2 have power equally distributed and transmitted to the hybrid coupler-2 C2 and the hybrid coupler-3 C3. This is because output matching of the power amplifier-1 PA1 and the power amplifier-2 PA2 is set to 2*Zo.

The 0-degree signal amplified at the power amplifier-1 PA1 may be converted into a 90-degree signal at the hybrid coupler-2 C2, and may be outputted to the antenna, and the 90-degree signal amplified at the power amplifier-2 PA2 may be outputted from the hybrid coupler-2 C2 to the antenna as the 90-degree signal.

As described above, the hybrid coupler-2 C2 converts the phase difference between the output signal of the power amplifier-1 PA1 and the output signal of the power amplifier-2 PA2 into 0 degree and transmits the signals to the antenna, such that the two signals having the same phase are combined with each other and are transmitted to the antenna.

Since the power amplifier-1 PA1 and the power amplifier-2 PA2 have the same output power as an existing power amplifier, and respective halves of the output power are combined at the hybrid coupler-2 C2, DC power consumption is high in comparison to that of an existing structure, but output power reflects only the loss of C2. Therefore, the output power may be deemed to have a low loss.

Meanwhile, the 0-degree signal amplified at the power amplifier-1 PA1 may be outputted from the hybrid coupler-3 C3 to the reception end Rx as the 0-degree signal, and the 90-degree signal amplified at the power amplifier-2 PA2 may be converted into a 180-degree signal at the hybrid coupler-3 C3 and may be outputted to the reception end Rx.

As described above, since the hybrid coupler-3 C3 converts the phase difference between the output signal of the power amplifier-1 PA1 and the output signal of the power amplifier-2 PA2 into 180 degrees, the two signals are offset and are not transmitted to the reception end Rx. That is, the reception end Rx is isolated from the transmission end Tx and power transmitted to the other output end of the hybrid coupler-3 C3 is absorbed by a resistance.

As described above, the quasi-circulator according to an embodiment guarantees a path from the transmission end Tx to the antenna, whereas it is identified that a path from the transmission end Tx to the reception end Rx is isolated. In addition, since a loss occurs only at the hybrid coupler-2 C2 on the path from the transmission end Tx to the antenna, the quasi-circulator of the low-loss may be implemented.

Hereinafter, a reception mode operation of the quasi-circulator according to an embodiment will be described in detail.

The hybrid coupler-2 C2 distributes a reception signal inputted through the antenna into two signals having a phase difference of 90 degrees (a signal having a phase of 90 degrees and a signal having a phase of 0 degree), and outputs the signals.

The 90-degree signal outputted from the hybrid coupler-2 C2 is outputted to the reception end Rx at the hybrid coupler-3 C3 as the 90-degree signal, and the 0-degree signal outputted from the hybrid coupler-2 C2 is converted into a 90-degree signal at the hybrid coupler-3 C3 and is outputted to the reception end Rx.

That is, the hybrid coupler-3 C3 converts the phase difference of the output signals of the hybrid coupler-2 C2 into 0 degree, and transmits the signals to the reception end Rx, such that the two signals are combined with each other and are inputted to the reception end Rx.

The signals outputted from the hybrid coupler-2 C2 are blocked at the power amplifiers PA1, PA2 and a leakage of signals does not occur due to reverse isolation, and the signals do not flow into the hybrid coupler-1 C1 and are not inputted to the transmission end Tx.

As described above, since only two insertion losses of the hybrid coupler-1 C1 and the hybrid coupler-2 C2 occur on the path from the antenna to the reception end Rx, there is an effect that the loss in this path is noticeably reduced.

In a related-art structure, a loss of 3.5 dB occurs in Tx-to-Antenna and a loss of 3.5 dB occurs in Antenna-to-Rx due to coupler distribution of 3 dB+ and a coupler insertion loss of 0.5 dB. However, in the quasi-circulator according to an embodiment, a loss in Tx-to-Antenna is merely 0.5 dB and a loss in Antenna-to-Rx is merely 1 dB.

Up to now, the low-loss quasi circulator has been described in detail with reference to preferred embodiments. Embodiments described above suggests a structure of a circulator which minimizes a loss in order to enhance efficiency of an RF FEM of an ultrahigh frequency radar system.

The quasi-circulator according to an embodiment is applicable to a communication system which uses a full duplex in which a transmission frequency and a reception frequency are the same, in addition to the radar system.

In addition, while preferred embodiments of the present disclosure have been illustrated and described, the present disclosure is not limited to the above-described specific embodiments. Various changes can be made by a person skilled in the art without departing from the scope of the present disclosure claimed in claims, and also, changed embodiments should not be understood as being separate from the technical idea or prospect of the present disclosure.

What is claimed is:

1. A quasi-circulator comprising:
a first coupler having an input end connected to a transmission end;
a first amplifier having an input end connected to an output end of the first coupler;
a second amplifier having an input end connected to the output end of the first coupler;
a second coupler having one end connected to an output end of the first amplifier and an output end of the second amplifier, and the other end connected to an antenna; and
a third coupler having one end connected to the output end of the first amplifier and the output end of the second amplifier, and the other end connected to a reception end.

2. The quasi-circulator of claim 1, wherein the first coupler is configured to distribute a transmission signal inputted through the input end into two signals having a phase difference of 90 degrees, and to output the signals,
wherein the first amplifier is configured to amplify one of the signals outputted from the output end of the first coupler,
wherein the second amplifier is configured to amplify the other one of the signals outputted from the output end of the first coupler, and
wherein the second coupler is configured to convert the phase difference between the output signal of the first amplifier and the output signal of the second amplifier into 0 degree, and to transmit the signals to the antenna.

3. The quasi-circulator of claim 1, wherein the signals outputted from the first amplifier and the second amplifier have power equally distributed and transmitted to the second coupler and the third coupler.

4. The quasi-circulator of claim 3, wherein an impedance when the second coupler and the third coupler are seen from the output end of the first amplifier is a sum of an impedance of the second coupler and an impedance of the third coupler,
wherein an impedance when the second coupler and the third coupler are seen from the output end of the second amplifier is the sum of the impedance of the second coupler and the impedance of the third coupler, and
wherein the impedance of the second coupler is equal to the impedance of the third coupler.

5. The quasi-circulator of claim 3, wherein the third coupler is configured to offset the phase difference between the output signal of the first amplifier and the output signal of the second amplifier by converting the phase difference into 180 degrees.

6. The quasi-circulator of claim 1, wherein the second coupler is configured to distribute a reception signal inputted through the antenna into two signals having a phase difference of 90 degrees, and to output the signals, wherein the third coupler is configured to convert the phase difference between output signals of the second coupler into 0 degree and to transmit the signals to the reception end.

7. The quasi-circulator of claim 6, wherein the first amplifier and the second amplifier are configured to block the output signals of the second coupler.

8. A communication method comprising the steps of:
distributing, by a first coupler, a transmission signal inputted from a transmission end into two signals, and output the signals;
amplifying, by a first amplifier, one of the distributed transmission signals;
amplifying, by a second amplifier, the other one of the distributed transmission signals;
transmitting, by a second coupler, the amplified transmission signals to an antenna; and
offsetting, by a third coupler, the amplified transmission signals at a reception end.
